(19) United States
(12) Patent Application Publication
(10) Pub. No.: US 2020/0303280 A1
(43) Pub. Date: Sep. 24, 2020

(54) THERMALLY ENHANCED ASSEMBLY WITH METALLIC INTERFACIAL STRUCTURE BETWEEN HEAT GENERATING COMPONENT AND HEAT SPREADER

(71) Applicant: BRIDGE SEMICONDUCTOR CORP., Taipei City (TW)

(72) Inventor: Charles W. C. LIN, Singapore (SG)

(21) Appl. No.: 16/823,895

(22) Filed: Mar. 19, 2020

Related U.S. Application Data
(60) Provisional application No. 62/821,059, filed on Mar. 20, 2019.

(51) Int. Cl. H01L 23/367; H01L 23/373; C25D 7/12

(52) U.S. Cl. CPC H01L 23/3675; C25D 7/12; H01L 23/3736

(57) ABSTRACT

An integrally formed metal layer is plated on spacers and a top surface of the heat spreader and a bottom surface of a heat generating component to establish a metallic interfacial structure that connects the heat generating component to the heat spreader. Accordingly, the heat can be conducted from the heat generating component to the heat spreader primarily through the metallic interfacial structure and the spacers.

### CROSS REFERENCE TO RELATED APPLICATIONS

This application claims the benefit of filing date of U.S. Provisional Application Ser. No. 62/821,059 filed Mar. 20, 2019. The entirety of said Provisional Application is incorporated herein by reference.

### FIELD OF THE INVENTION

The present invention relates to a thermally enhanced assembly and, more particularly, to a thermally enhanced assembly having a metallic interfacial structure between a heat generating component and a heat spreader.

### DESCRIPTION OF RELATED ART

Semiconductor devices are susceptible to performance degradation as well as short life span and may even suffer immediate failure at high operating temperatures. As such, when a semiconductor chip is assembled into a package, it often requires effective heat dissipation pathway so that the heat generated by the chip can flow to the ambient environment for a reliable operation.

Convention approaches for enhancing heat dissipation include attaching a heat generating component to a heat spreader by mechanical fastening or through thermally conductive adhesive or soldering materials. Mechanical fastening can't provide a complete contact interface if either surface is not micron-scale smooth. Thermally conductive adhesive and soldering material are less effective as their thermally conductivities are low for certain ultra-high heat transfer requirements.

### SUMMARY OF THE INVENTION

An objective of the present invention is to provide a metallic interfacial structure for conducting heat from a heat generating component to a heat spreader. As the interfacial structure is deposited by electroplating, the heat generating component and the heat spreader can be securely joined together as a single and permanent piece, and cannot be easily dismantled without destroying the integrity of the piece.

In accordance with the foregoing and other objectives, the present invention provides a thermally enhanced assembly, comprising: a heat spreader, having an electrically conductive top surface; a plurality of spacers, projecting from the electrically conductive top surface of the heat spreader; a heat generating component, having a bottom surface facing in and spaced from the electrically conductive top surface of the heat spreader by a distance, wherein the distance is equal to or greater than projecting height of the spacers; and a metallic interfacial structure, having an upper portion covering the bottom surface of the heat generating component, a lower portion covering the electrically conductive top surface of the heat spreader, and linking portions covering sidewall surfaces of the spacers and connecting the upper portion to the lower portion, wherein the upper portion and the lower portion are spaced from each other by a gap and integrated with the linking portions.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of a heat spreader provided with spacers in accordance with the first embodiment of the present invention;

FIG. 3 is a cross-sectional view of the structure of FIG. 1 further provided with a heat generating component in accordance with the first embodiment of the present invention;

FIG. 4 is a cross-sectional view of the structure of FIG. 3 further provided with a metal-plating layer by electroplating in accordance with the first embodiment of the present invention;

FIG. 5 is a cross-sectional view of the structure of FIG. 4 continuously subjected to electroplating in accordance with the first embodiment of the present invention;

FIG. 6 is a cross-sectional view of a resulting thermally enhanced assembly in accordance with the first embodiment of the present invention;

FIG. 7 is an enlarged view of a circled portion in FIG. 6;

FIG. 8 is a cross-sectional view of the structure with a heat generating component placed above and spaced from a heat spreader 11 by spacers in accordance with the second embodiment of the present invention;

FIG. 9 is a cross-sectional view of the structure of FIG. 8 further provided with a metallic interfacial structure to accomplish the fabrication of a thermally enhanced assembly in accordance with the second embodiment of the present invention;

FIG. 10 is a cross-sectional view of the structure of FIG. 1 provided with a binding material in accordance with the third embodiment of the present invention;

FIG. 11 is a cross-sectional view of the structure of FIG. 10 provided with a heat generating component in accordance with the third embodiment of the present invention;

FIG. 12 is a cross-sectional view of the structure of FIG. 11 further provided with a metallic interfacial structure to accomplish the fabrication of a thermally enhanced assembly in accordance with the third embodiment of the present invention;

FIG. 13 is a cross-sectional view of a heat spreader provided with spacers in accordance with the fourth embodiment of the present invention;

FIG. 14 is a cross-sectional view of the structure of FIG. 13 provided with a heat generating component in accordance with the fourth embodiment of the present invention; and

FIG. 15 is a cross-sectional view of the structure of FIG. 14 further provided with a metallic interfacial structure to accomplish the fabrication of a thermally enhanced assembly in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

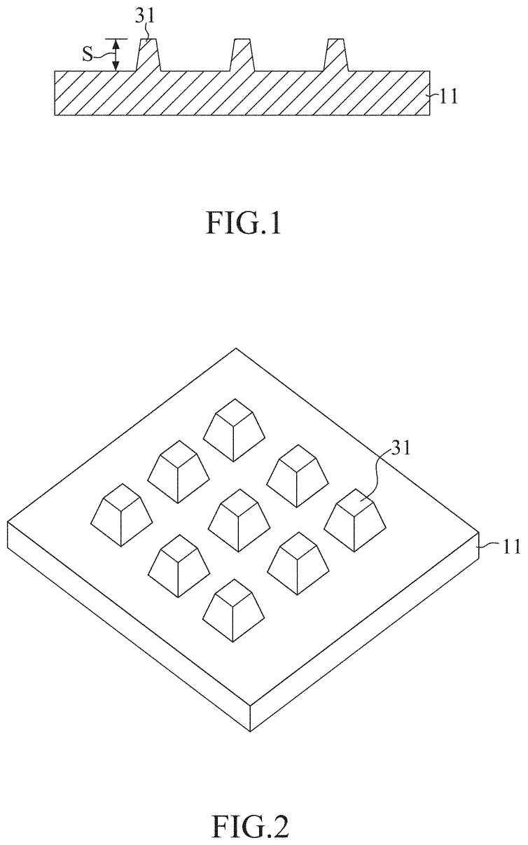

FIGS. 1-9 are schematic views showing a method of making a thermally enhanced assembly that includes a heat spreader, a plurality of spacers, a heat generating component and a metallic interfacial structure in accordance with the first embodiment of the present invention.

FIGS. 1 and 2 are cross-sectional and top perspective views, respectively, of a heat spreader 11 provided with a plurality of spacers 31 thereon. The heat spreader 11 can be made of any material with high thermal conductivity, such as metal or alloy. Additionally, for subsequent electroplating, the heat spreader 11 preferably is electrically conductive or at least its surface is coated with an electrically conductive material. Accordingly, the heat spreader 11 can have an electrically conductive top surface. The spacers 31 may be formed by chemical plating, etching or mechanical method such as stud bumping, and project from the electrically conductive top surface of the heat spreader 11 by a predetermined projecting height S. Preferably, the projecting height S of the spacers 31 is in a range of 10 μm to 100 μm. The spacers 31 can be electrically conductive or at least its top surface and sidewall surfaces are coated with an electrically conductive material. In this embodiment, the spacers 31 are integrated with the heat spreader 11 and have electrically conductive top and sidewall surfaces.

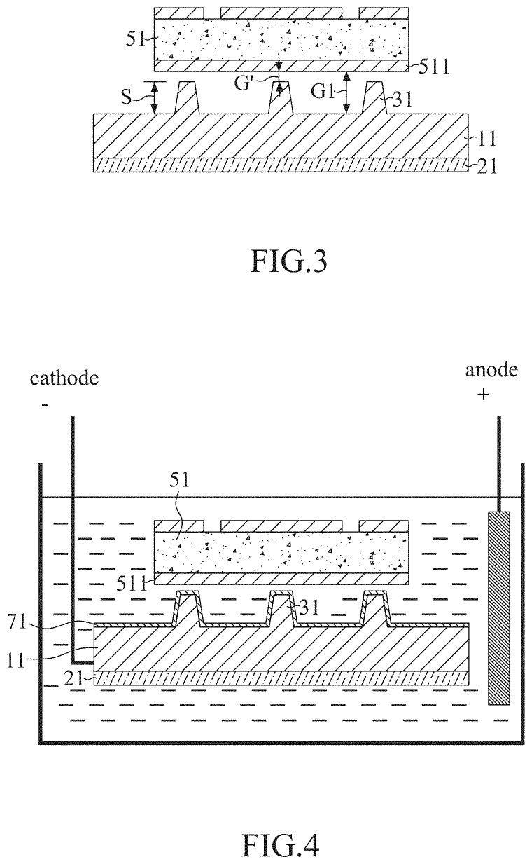

FIG. 3 is a cross-sectional view of the structure with a heat generating component 51 provided above the spacers 31. The heat generating component 51 may be an electronic device or a thermally conductive substrate such as ceramic plate that can conduct heat originated from another source. In this embodiment, the heat generating component 51 is illustrated as a thermally conductive substrate, and optionally has an electrically conductive layer 511 at its bottom surface facing in the electrically conductive top surface of the heat spreader 11. The electrically conducive bottom surface of the heat generating component 51 is spaced from the electrically conductive top surface of the heat spreader 11 by a distance G1 larger than or equal to the projecting height S of the spacers 31. Preferably, the distance G1 is in a range of 10 μm to 110 μm. In this illustration, the distance G1 is larger than the projecting height S of the spacers 31, and the bottom surface of the heat generating component 51 is spaced from the top surface of the spacers 31 by a gap G′. Preferably, the gap G′ is 10 μm or less. Optionally, an insulator film 21 may be attached to the bottom surface of the heat spreader 11.

FIG. 4 is a cross-sectional view of the structure provided with a metal-plating layer 71 on the heat spreader 11 as well as the spacers 31. The heat generating component 51 and the heat spreader 11 are immersed in an electrolyte solution and current is applied at the heat spreader 11 as the cathode. The electrolyte can flow in between the spacers 31, and cations are reduced at the heat spreader 11 to form the metal-plating layer 71 on the top surface of the heat spreader 11 as well as the top surface and the sidewall surfaces of the spacers 31 by electroplating process in this embodiment. Alternatively, in accordance with other aspects, if the electrolyte solution contains reducing agent that can reduce cations through electrochemical reaction, the top surface of the heat spreader 11, the top surface and the sidewall surfaces of the spacers 31 and the bottom surface of the heat generating component 51 may be first coated with an electroless metal layer before the electroplating process.

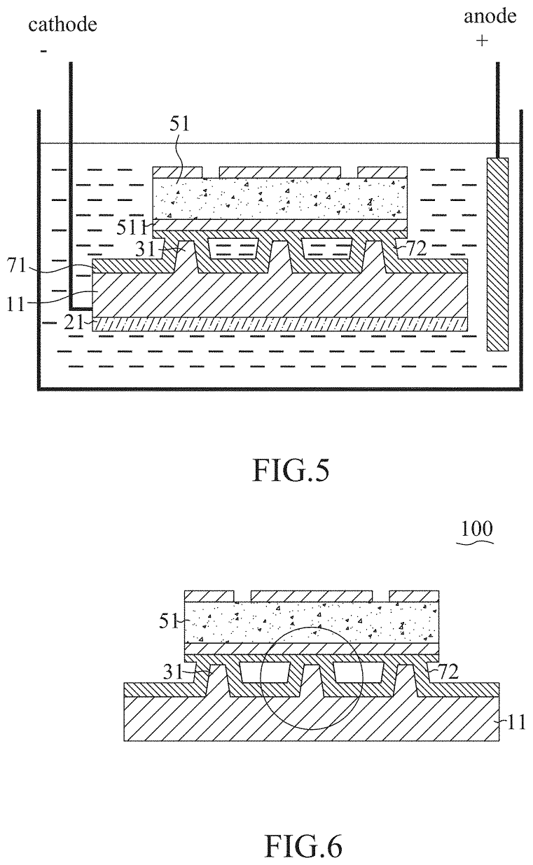

FIG. 5 is a cross-sectional view of the structure with the metal-plating layer 71 being thickened and further deposited on the bottom surface of the heat generating component 51. The metal-plating layer 71 formed on the heat spreader 11 and the spacers 31 is thickened during the electroplating process. Upon the metal-plating layer 71 contacts the electrically conductive layer 511 of the heat generating component 51, the bottom surface of the heat generating component 51 is also plated with the metal-plating layer 71. The electroplating process is continuously executed until the integrally formed metal-plating layer 71 reaches desirable thickness. As a result, a metallic interfacial structure 72 is established to connect the heat spreader 11 with the heat generating component 51.

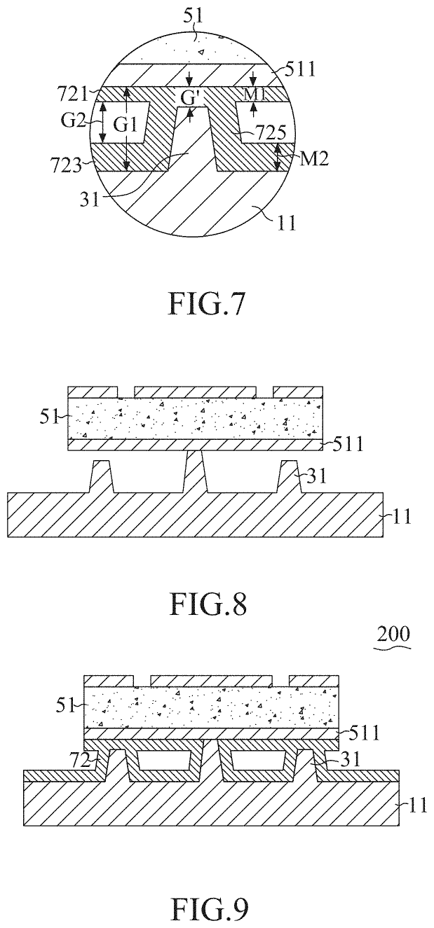

FIG. 6 is a cross-sectional view of the resulting thermally enhanced assembly 100, while FIG. 7 is an enlarged view of a circled portion in FIG. 6. The insulator film 21 is removed from the bottom surface of the heat spreader 11, and the thermally enhanced assembly 100 is accomplished and includes the heat spreader 11, the spacers 31, the heat generating component 51 and the metallic interfacial structure 72. By the metallic interfacial structure 72, the heat spreader 11 and the heat generating component 51 are connected together to work together as a single complete and substantially permanent piece. The metallic interfacial structure 72 has an upper portion 721, a lower portion 723 and linking portions 725 and is incapable of being easily dismantled without destroying the integrity of the piece. The upper portion 721 of the metallic interfacial structure 72 is deposited in a thickness M1 and covers the bottom surface of the heat generating component 51. The lower portion 723 of the metallic interfacial structure 72 is deposited in a thickness M2 and covers the electrically conductive top surface of the heat spreader 11. The linking portions 725 of the metallic interfacial structure 72 cover the sidewall surfaces of the spacers 31 and connect the upper portion 721 to the lower portion 723. In this illustration, the thickness M2 of the lower portion 723 is greater than the thickness M1 of the upper portion 721, and the linking portions 725 of the metallic interfacial structure 72 further fill in the gap G′ between the top surface of the spacers 31 and the bottom surface of the heat generating component 51. As shown in FIG. 7, the upper portion 721 and the lower portion 723 of the metallic interfacial structure 72 are spaced from each other by a gap G2, and the metallic interfacial structure 72 meets the relationship: G1=G2+M1+M2.

### Embodiment 2

FIGS. 8-9 are cross-sectional views showing a method of making a thermally enhanced assembly in accordance with the second embodiment of the present invention.

For purposes of brevity, any description in Embodiment 1 is incorporated herein in so far as the same is applicable, and the same description need not be repeated.

FIG. 8 is a cross-sectional view of the structure with the heat generating component 51 placed above and spaced from the heat spreader 11 by the spacers 31. The heat spreader 11, the spacers 31 and the heat generating component 51 are similar to those illustrated in Embodiment 1, except that at least one of the spacers 31 is taller than the others. In this illustration, the bottom surface of the heat generating component 51 contacts the top surface of the taller one of the spacers 31.

FIG. 9 is a cross-sectional view of the resulting thermally enhanced assembly 200. By electroplating, a metallic interfacial structure 72 is deposited on and contacts the heat spreader 11, the spacers 31 and the electrically conductive layer 511 of the heat generating component 51. As a result, the heat can be conducted from the heat generating component 51 to the heat spreader 11 primarily through the metallic interfacial structure 72 and the spacers 31.

### Embodiment 3

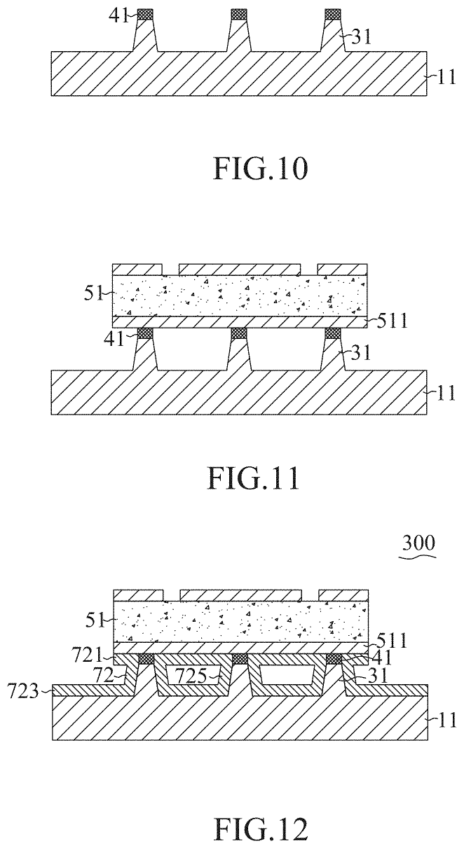

FIGS. 10-12 are cross-sectional views showing a method of making a thermally enhanced assembly in accordance with the third embodiment of the present invention.

For purposes of brevity, any description in the Embodiments above is incorporated herein in so far as the same is applicable, and the same description need not be repeated.

FIG. 10 is a cross-sectional view of the structure of FIG. 1 provided with a binding material 41. The top surface of the spacers 31 is provided with the binding material 41 thereon. The binding material 41 may be a soldering material or any other electrically conductive or non-conductive material.

FIG. 11 is a cross-sectional view of the structure with a heat generating component 51 provided above the spacers 31. The heat generating component 51 is the same as that illustrated in Embodiment 1 and attached to the top surface of the spacers 31 through the binding material 41 in contact with the electrically conductive layer 511 of the heat generating component 51.

FIG. 12 is a cross-sectional view of the resulting thermally enhanced assembly 300. By electroplating, a metallic interfacial structure 72 is deposited and has an upper portion 721 under the bottom surface of the heat generating component 51, a lower portion 723 on the top surface of the heat spreader 11, and linking portions 725 laterally covering the sidewall surfaces of the spacers 31 as well as the binding material 41. As a result, the thermally enhanced assembly 300 is accomplished and includes the heat spreader 11, the spacers 31, the binding material 41, the heat generating component 51 and the metallic interfacial structure 72.

### Embodiment 4

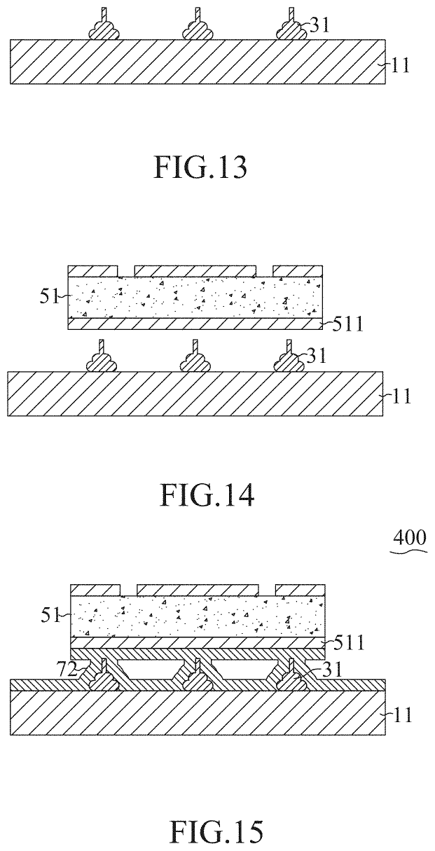

FIGS. 13-15 are cross-sectional views showing a method of making a thermally enhanced assembly in accordance with the fourth embodiment of the present invention.

For purposes of brevity, any description in the Embodiments above is incorporated herein in so far as the same is applicable, and the same description need not be repeated.

FIG. 13 is a cross-sectional view of the structure with a plurality of spacers 31 on a head spreader 11. In this embodiment, the spacers 31 are mechanically attached on the top surface of the heat spreader 11. For subsequent electroplating, the spacers 31 preferably are made of an electrically conductive material.

FIG. 14 is a cross-sectional view of the structure with a heat generating component 51 provided above the spacers 31. The heat generating component 51 is disposed in close proximity to and spaced from the top surface of the spacers 31 by a gap.

FIG. 15 is a cross-sectional view of the resulting thermally enhanced assembly 400. By electroplating, a metallic interfacial structure 72 covers the top surface of the heat spreader 11, the sidewall surfaces of the spacers 31 and the bottom surface of the heat generating component 51, and fills in the gap between the spacers 31 and the heat generating component 51. As a result, the metallic interfacial structure 72 can facilitate heat dissipation from the heat generating component 51 to the heat spreader 11.

As illustrated in the aforementioned embodiments, a distinctive metallic interfacial structure can be formed between a heat spreader and a heat generating component by steps of: placing the heat spreader and the heat generating component in an electrolyte solution, with the heat generating component being spaced from the heat spreader by a plurality of spacers which project from a surface of the heat spreader and are in close proximity to or in contact with a surface of the heat generating component; and using the heat spreader as a cathode to perform electroplating so as to deposit the metallic interfacial structure over the surfaces facing each other of the heat spreader and the spacers as well as sidewall surfaces of the metallic interfacial structure. Accordingly, a thermally enhanced assembly is accomplished and mainly includes the heat spreader, the plurality of spacers, the heat generating component and the metallic interfacial structure.

The thermally enhanced assemblies described above are merely exemplary. Numerous other embodiments are contemplated. In addition, the embodiments described above can be mixed-and-matched with one another and with other embodiments depending on design and reliability considerations. For the convenience of description, the surfaces, facing in the heat generating component, of the heat spreader and the spacers are defined as the top surfaces, and the surface, facing in the heat spreader, of the heat generating component is defined as the bottom surface.

The heat spreader can be a metal or alloy plate or any other thermally conductive plate to serve as a primary heat conduction platform, so that the heat from the heat generating component can be conducted away. For being a cathode in an electroplating process, the heat spreader preferably is electrically conductive at least at its top surface. Accordingly, an electroplated metal layer can be deposited on the top surface of the heat spreader and grown to form the metallic interfacial structure.

The spacers can have the same or different projecting height, and preferably are electrically conductive at their sidewall surfaces and optionally their top surfaces. As a result, the electroplated metal layer can also be deposited on the sidewall surfaces of the spacers by the electroplating process using the heat spreader as the cathode. In accordance with one embodiment, the top surface of at least one spacer is spaced from the bottom surface of the heat generating component by a gap of 10 micrometers or less or attached to the bottom surface of the heat generating component by a binding material. Upon the electroplated metal layer contacts the bottom surface of the heat generating component by the growth of the electroplated metal layer on the sidewall surfaces of the spacers, the electroplated metal layer can also be deposited on the bottom surface of the heat generating component by the electroplating process using the heat spreader as the cathode. Alternatively, the top surface of at least one spacer may contact and be electrically conductible to the bottom surface of the heat generating component so as to allow the electroplated metal layer to be deposited on the top surface of the heat spreader, the sidewall surfaces of the spacers and the bottom surface of the heat generating component by the electroplating process using the heat spreader as the cathode.

The heat generating component may be an electronic device or a thermally conductive substrate that can conduct heat originated from another source. The bottom surface of the heat generating component preferably is electrically conductive so as to allow the deposition of the electroplated metal layer under the bottom surface of the heat generating component by the electroplating process using the heat spreader as the cathode. For instance, the heat generating component may include an electrically conductive layer at its bottom surface.

The metallic interfacial structure is electrically and thermally conductible to the heat spreader and the heat generating component as well as the spacers. More specifically, the metallic interfacial structure can have an upper portion under the bottom surface of the heat generating component, a lower portion over the top surface of the heat spreader, and linking portions extending from the lower portion to the upper portion and covering the sidewall surfaces of the spacers. In the aspect of the spacers being spaced from the heat generating component, the linking portions further fill in the gap between the top surface of the spacers and the bottom surface of the heat generating component, and the lower portion has a greater thickness than the upper portion. In another aspect of the spacers being attached to the heat generating component by the binding material, the linking portions further laterally covers the binding material.

The “upper” and “lower” portions of the metallic interfacial structure and the “top” and “bottom” surfaces of the heat spreader, the spacers and the heat generating component do not depend on the orientation of the assembly, as will be readily apparent to those skilled in the art. For instance, the upper portion of the metallic interfacial structure adjacent to the bottom surface of the heat generating component, and the lower portion of the metallic interfacial structure adjacent to the top surface of the heat spreader, regardless of whether the assembly is inverted. Similarly, the “top” surface of the heat spreader and the “bottom surface” of the heat generating component faces each other, regardless of whether the assembly is inverted, rotated or slanted.

The term “cover” refers to incomplete or complete coverage in a vertical and/or lateral direction. For instance, in a preferred embodiment, the metallic interfacial structure completely covers the bottom surface of the heat generating component, the top surface of the heat spreader and the sidewall surfaces of the spacers regardless of whether another element is between the metallic interfacial structure and the heat generating component, between the metallic interfacial structure and the heat spreader and between the metallic interfacial structure and the spacers.

The thermally enhanced assembly made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A thermally enhanced assembly, comprising:
a heat spreader, having an electrically conductive top surface;
a plurality of spacers, projecting from the electrically conductive top surface of the heat spreader;
a heat generating component, having a bottom surface facing in and spaced from the electrically conductive top surface of the heat spreader by a distance, wherein the distance is equal to or greater than projecting height of the spacers; and
a metallic interfacial structure, having an upper portion covering the bottom surface of the heat generating component, a lower portion covering the electrically conductive top surface of the heat spreader, and linking portions covering sidewall surfaces of the spacers and connecting the upper portion to the lower portion, wherein the upper portion and the lower portion are spaced from each other by a gap and integrated with the linking portions.

2. The thermally enhanced assembly of claim 1, wherein the metallic interfacial structure is an integrally formed metal-plating layer.

3. The thermally enhanced assembly of claim 1, wherein the metallic interfacial structure is integrally formed by electroplating.

4. The thermally enhanced assembly of claim 1, wherein at least one of the spacers has a top surface spaced from the bottom surface of the heat generating component, and the linking portions of the metallic interfacial structure further fill in a gap between the top surface of the spacer and the bottom surface of the heat generating component.

5. The thermally enhanced assembly of claim 1, wherein at least one of the spacers has a top surface in contact with the bottom surface of the heat generating component.

6. The thermally enhanced assembly of claim 1, wherein at least one of the spacers has a top surface attached to the bottom surface of the heat generating component by a binding material, and the linking portions of the metallic interfacial structure further laterally cover the binding material.

7. The thermally enhanced assembly of claim 4, wherein the gap between the top surface of the spacer and the bottom surface of the heat generating component is 10 μm or less.

8. The thermally enhanced assembly of claim 1, wherein the thickness of the lower portion is greater than that of the upper portion.

9. The thermally enhanced assembly of claim 1, wherein the spacers are electrically conductive.

10. The thermally enhanced assembly of claim 1, wherein the heat generating component includes an electrically conductive layer at the bottom surface thereof.
